(19) United States
(12) Patent Application Publication
(10) Pub. No.: US 2026/0066877 A1
(43) Pub. Date: Mar. 5, 2026

(54) COMPOSITE FILTER DEVICE

(71) Applicant: Murata Manufacturing Co., Ltd., Nagaokakyo-shi (JP)

(72) Inventor: Hiroyuki YOSHIOKA, Nagaokakyo-shi (JP)

(21) Appl. No.: 19/381,040

(22) Filed: Nov. 6, 2025

Related U.S. Application Data
(63) Continuation of application No. PCT/JP2024/015912, filed on Apr. 23, 2024.

(30) Foreign Application Priority Data
May 10, 2023 (JP) 2023-078042

(51) Int. Cl. H03H 9/64; H03H 9/72

(52) U.S. Cl. CPC H03H 9/6433; H03H 9/725

(57) ABSTRACT

A composite filter device includes a piezoelectric substrate, a first filter that is a band pass filter and includes a longitudinally coupled resonator-type acoustic wave filter on the piezoelectric substrate, a second filter that includes at least one resonator and an inductor connected to a reference potential, and a reference potential wiring line on the piezoelectric substrate and connected to the reference potential, that has a substantially annular portion having an annular shape including a gap, and that surrounds, in the substantially annular portion, the longitudinally coupled resonator-type acoustic wave filter. The substantially annular portion of the reference potential wiring line includes first and second end portions facing each other across the gap, and a reference potential connection portion extending with the first end portion as a starting point and that connects the longitudinally coupled resonator-type acoustic wave filter to the reference potential.

### CROSS REFERENCE TO RELATED APPLICATIONS

This application claims the benefit of priority to Japanese Patent Application No. 2023-078042 filed on May 10, 2023 and is a Continuation Application of PCT Application No. PCT/JP2024/015912 filed on Apr. 23, 2024. The entire contents of each application are hereby incorporated herein by reference.

### BACKGROUND OF THE INVENTION

### 1. Field of the Invention

The present invention relates to composite filter devices.

### 2. Description of the Related Art

A composite filter device including acoustic wave resonator(s) is widely used in the related art as a filter for a cellular phone, and the like. International Publication No. 2013/141183 discloses an example of an acoustic wave demultiplexer as a composite filter device. Such an acoustic wave demultiplexer has two band pass filters. The two band pass filters are connected in common to an antenna terminal. Specifically, the two band pass filters are a transmission side filter chip and a reception side filter chip. The transmission side filter chip and the reception side filter chip are flip-chip mounted on a wiring substrate.

The wiring substrate has a plurality of dielectric layers. An inductor is provided over the plurality of dielectric layers. The inductor is connected between the antenna terminal and a ground potential. The inductor is used for impedance matching.

### SUMMARY OF THE INVENTION

There is a possibility that, in each of the band pass filters described in International Publication No. 2013/141183, out-band attenuation cannot be sufficiently increased.

Example embodiments of the present invention provide composite filter devices each capable of increasing an out-band attenuation of the band pass filter.

A composite filter device according to an example embodiment of the present invention includes a piezoelectric substrate, a first filter that is a band pass filter and that includes a longitudinally coupled resonator-type acoustic wave filter provided on the piezoelectric substrate, a second filter that includes at least one resonator and an inductor connected to a reference potential, and a reference potential wiring line that is a wiring line provided on the piezoelectric substrate and connected to the reference potential, that has a substantially annular portion having an annular shape including a gap, and that surrounds, in the substantially annular portion, the longitudinally coupled resonator-type acoustic wave filter. The substantially annular portion of the reference potential wiring line includes a first end portion and a second end portion that face each other across the gap, and a reference potential connection portion that extends with the first end portion as a starting point and that connects the longitudinally coupled resonator-type acoustic wave filter to the reference potential. The inductor includes one parallel wiring portion that extends in parallel or substantially in parallel with the reference potential connection portion in plan view, or two or more parallel wiring portions that extend in parallel or substantially in parallel with the reference potential connection portion and are arranged in a direction perpendicular to a direction in which the reference potential connection portion extends in plan view such that currents flowing through the two or more parallel wiring portions have the same direction. When a region including an area from a parallel wiring portion positioned on a side closest to one side in a direction perpendicular to a direction in which the parallel wiring portion extends to a parallel wiring portion positioned on a side closest to the other side in the direction perpendicular to the direction in which the parallel wiring portion extends is defined as a parallel wiring portion region, the parallel wiring portion region and the reference potential connection portion overlap with each other in plan view. A direction of a current flowing through the parallel wiring portion and a direction of a current flowing through the reference potential connection portion are the same.

With composite filter devices according to example embodiments of the present invention, it is possible to increase the out-band attenuation of the band pass filter.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a circuit diagram of a composite filter device according to a first example embodiment of the present invention.

FIG. 2 is a schematic transparent plan view of an acoustic wave element chip according to the first example embodiment of the present invention.

FIG. 3 is a transparent plan view showing the vicinity of a longitudinally coupled resonator-type acoustic wave filter of a first filter according to the first example embodiment of the present invention.

FIG. 4 is a schematic view showing the longitudinally coupled resonator-type acoustic wave filter, and wiring lines and a reference potential wiring line that are connected to the longitudinally coupled resonator-type acoustic wave filter, according to the first example embodiment of the present invention.

FIG. 5 is a schematic front sectional view of the composite filter device according to the first example embodiment of the present invention.

FIG. 6 is a plan view showing an electrode structure of a first layer of a mounting substrate according to the first example embodiment of the present invention.

FIG. 7 is a plan view showing an electrode structure of a second layer of the mounting substrate according to the first example embodiment of the present invention.

FIG. 8 is a plan view showing an electrode structure of a third layer of the mounting substrate according to the first example embodiment of the present invention.

FIG. 9 is a plan view showing an electrode structure of a fourth layer of the mounting substrate according to the first example embodiment of the present invention.

FIG. 10 is a plan view showing an electrode structure of a fifth layer of the mounting substrate according to the first example embodiment of the present invention.

FIG. 11 is a transparent plan view showing an electrode structure of a sixth layer of the mounting substrate according to the first example embodiment of the present invention.

FIG. 12 is an enlarged plan view showing a portion of an inductor of a second filter provided on the second layer of the mounting substrate according to the first example embodiment of the present invention.

FIG. 13 is a schematic bottom view showing the positional relationship between the reference potential wiring line and the inductor of the second filter in the first example embodiment of the present invention.

FIG. 14 is a transparent plan view showing the vicinity of a longitudinally coupled resonator-type acoustic wave filter of a first filter in a first comparative example.

FIG. 15 is a graph showing the attenuation-frequency characteristics of the first filter in the first example embodiment of the present invention and the attenuation-frequency characteristics of the first filter in the first comparative example, in a wide frequency range.

FIG. 16 is a graph showing the attenuation-frequency characteristics of the first filter in the first example embodiment of the present invention and the attenuation-frequency characteristics of the first filter in the first comparative example, in the vicinity of the pass band.

FIG. 17 is a graph showing the attenuation-frequency characteristics of the second filter in the first example embodiment of the present invention and the attenuation-frequency characteristics of the second filter in the first comparative example, in a wide frequency range.

FIG. 18 is a graph showing the attenuation-frequency characteristics of the second filter in the first example embodiment of the present invention and the attenuation-frequency characteristics of the second filter in the first comparative example, in the vicinity of the attenuation band.

FIG. 19 is a schematic view showing a longitudinally coupled resonator-type acoustic wave filter, and wiring lines and a reference potential wiring line that are connected to the longitudinally coupled resonator-type acoustic wave filter, in a second comparative example.

FIG. 20 is a schematic view showing a longitudinally coupled resonator-type acoustic wave filter, and wiring lines and a reference potential wiring line that are connected to the longitudinally coupled resonator-type acoustic wave filter, in a third comparative example.

FIG. 21 is a schematic view showing a longitudinally coupled resonator-type acoustic wave filter, and wiring lines and a reference potential wiring line that are connected to the longitudinally coupled resonator-type acoustic wave filter, in a fourth comparative example.

FIG. 22 is a schematic circuit diagram showing a composite filter device according to a modification of the first example embodiment of the present invention.

FIG. 23 is a schematic view showing a longitudinally coupled resonator-type acoustic wave filter, and wiring lines and a reference potential wiring line that are connected to the longitudinally coupled resonator-type acoustic wave filter, according to a second example embodiment of the present invention.

FIG. 24 is a schematic view showing a longitudinally coupled resonator-type acoustic wave filter, and wiring lines and a reference potential wiring line that are connected to the longitudinally coupled resonator-type acoustic wave filter, according to a third example embodiment of the present invention.

### DETAILED DESCRIPTION OF THE EXAMPLE EMBODIMENTS

Hereinafter, the present invention will be clarified by describing specific example embodiments of the present invention with reference to the accompanying drawings.

It should be noted that the example embodiments described in the present specification are exemplary, and that partial replacement or combination of configurations is possible between different example embodiments.

FIG. 1 is a circuit diagram of a composite filter device according to a first example embodiment of the present invention.

A composite filter device 10 includes a common connection terminal 3, a first filter 1A, and a second filter 1B. The first filter 1A and the second filter 1B are connected in common to the common connection terminal 3. The common connection terminal 3 is an antenna terminal in the present example embodiment. The antenna terminal is connected to an antenna. An inductor L1 is connected between the common connection terminal 3 and the first filter 1A and second filter 1B.

The first filter 1A is a band pass filter. More specifically, the first filter 1A is a reception filter. On the other hand, the second filter 1B is a band elimination filter. Therefore, the composite filter device 10 is an extractor.

The first filter 1A includes a first signal terminal 4A, a longitudinally coupled resonator-type acoustic wave filter 6, a plurality of acoustic wave resonators, and an inductor L2. The longitudinally coupled resonator-type acoustic wave filter 6 is connected between the common connection terminal 3 and the first signal terminal 4A. In the present example embodiment, the longitudinally coupled resonator-type acoustic wave filter 6 has a configuration of one stage of 5IDT type. Note that the configuration of the longitudinally coupled resonator-type acoustic wave filter 6 is not limited to the configuration described above.

Specifically, the plurality of acoustic wave resonators of the first filter 1A include an acoustic wave resonator S1, an acoustic wave resonator S2, and an acoustic wave resonator P1. The acoustic wave resonator S1 and the acoustic wave resonator S2 are connected in series between the longitudinally coupled resonator-type acoustic wave filter 6 and the common connection terminal 3. The acoustic wave resonator P1 is connected between a connection point between the acoustic wave resonator S1 and the acoustic wave resonator S2 and a reference potential. The inductor L2 is connected between the longitudinally coupled resonator-type acoustic wave filter 6 and the first signal terminal 4A.

The second filter 1B includes a second signal terminal 4B, a plurality of acoustic wave resonators, and a plurality of inductors. Specifically, the plurality of acoustic wave resonators of the second filter 1B include an acoustic wave resonator S11, an acoustic wave resonator S12, and an acoustic wave resonator S13. The acoustic wave resonator S11, the acoustic wave resonator S12, and the acoustic wave resonator S13 are connected in series with each other between the common connection terminal 3 and the second signal terminal 4B.

Specifically, the plurality of inductors of the second filter 1B include an inductor L3, an inductor L4, an inductor L5, and an inductor L6. The inductor L3 is connected between the common connection terminal 3 and the acoustic wave resonator S11. The inductor L4 is connected between a connection point between the acoustic wave resonator S11 and the acoustic wave resonator S12 and the reference potential. The inductor L5 is connected between a connection point between the acoustic wave resonator S12 and the acoustic wave resonator S13 and the reference potential. The inductor L6 is connected between the acoustic wave resonator S13 and the second signal terminal 4B. The circuit configuration of the composite filter device 10 is not limited to the configuration described above.

The first filter 1A is a band pass filter that outputs, among signals inputted from the common connection terminal 3, a signal having a frequency in a predetermined band to the first signal terminal 4A. The second filter 1B is a band elimination filter that outputs, among signals inputted from the common connection terminal 3, a signal having a frequency outside the predetermined band to the second signal terminal 4B. The first filter 1A and the second filter 1B are configured by one acoustic wave element chip. A specific configuration of the composite filter device 10 will be described below.

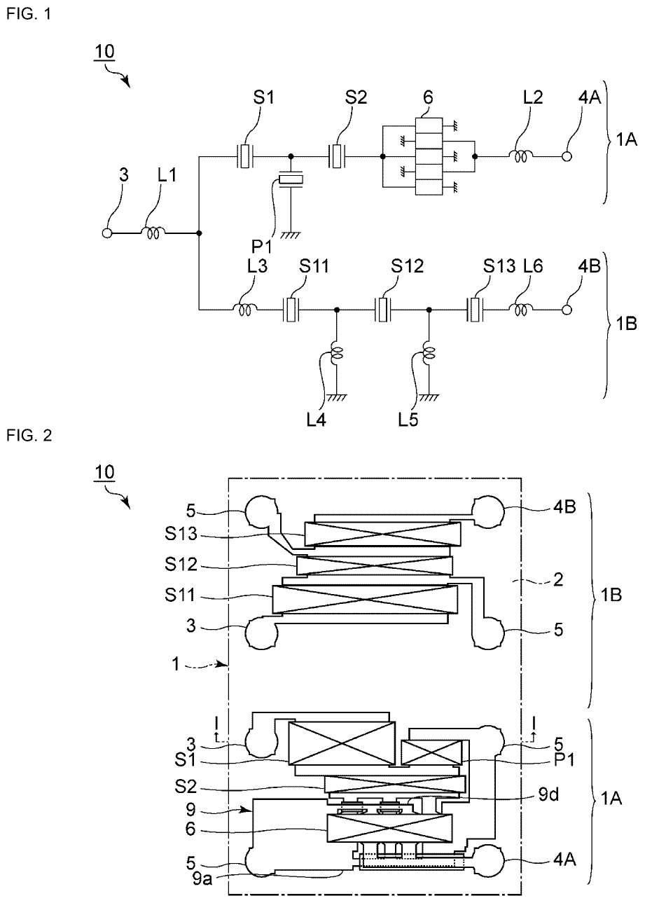

FIG. 2 is a schematic transparent plan view of the acoustic wave element chip according to the first example embodiment. In FIG. 2, resonators are each shown by a schematic diagram obtained by adding two diagonals to a rectangle. The same goes for the following schematic plan view, schematic bottom view, and schematic sectional view.

An acoustic wave element chip 1 of the composite filter device 10 includes a piezoelectric substrate 2. The piezoelectric substrate 2 is a substrate having piezoelectricity. In the present example embodiment, the piezoelectric substrate 2 is a substrate made of only a piezoelectric material. For example, lithium tantalate, lithium niobate, zinc oxide, aluminum nitride, quartz crystal, or lead zirconate titanate (PZT) can be used as the piezoelectric material. However, the piezoelectric substrate 2 may also be a multilayer substrate including a piezoelectric layer.

Each resonator of the composite filter device 10 is configured on the piezoelectric substrate 2. Each terminal of the composite filter device 10 is provided as an electrode pad on the piezoelectric substrate 2. The common connection terminal 3 of the first filter 1A and the common connection terminal 3 of the second filter 1B are provided on the piezoelectric substrate 2. The two common connection terminals 3 are shared in a portion other than the piezoelectric substrate 2. Further, a plurality of reference potential terminals 5 are provided on the piezoelectric substrate 2. The reference potential terminals 5 are connected to the reference potential.

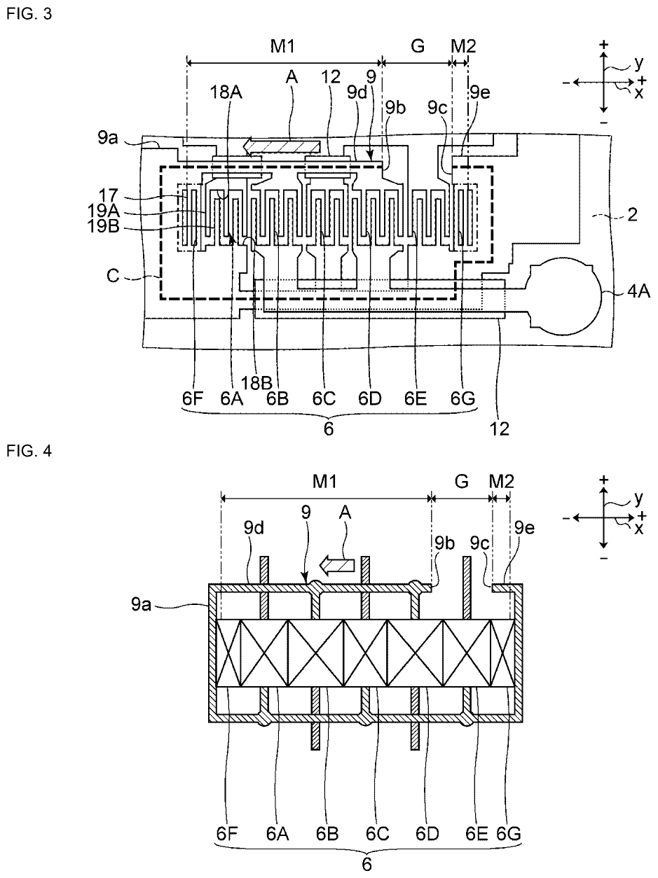

FIG. 3 is a transparent plan view showing the vicinity of the longitudinally coupled resonator-type acoustic wave filter of the first filter according to the first example embodiment. A broken line C in FIG. 3 indicates that a reference potential wiring line 9 described later surrounds the longitudinally coupled resonator-type acoustic wave filter 6. It should be noted that the broken line C does not indicate the reference potential wiring line 9 itself.

The longitudinally coupled resonator-type acoustic wave filter 6 includes a plurality of IDT electrodes and a pair of reflectors. Each IDT electrode includes a pair of busbars and a plurality of electrode fingers. In each IDT electrode, one busbar of the pair of busbars is connected to the reference potential. The other busbar is connected to a signal potential.

The reference potential wiring line 9 is provided on the piezoelectric substrate 2, in a portion around the longitudinally coupled resonator-type acoustic wave filter 6. The reference potential wiring line 9 is connected to the reference potential. Specifically, the reference potential wiring line 9 is connected to the reference potential terminal 5 shown in FIG. 2. The reference potential wiring line 9 is connected to the reference potential via the reference potential terminal 5.

The reference potential wiring line 9 includes a substantially annular portion 9a. Specifically, the substantially annular portion 9a is a portion obtained by cutting an annular shape at one place. In other words, the substantially annular portion 9a has an annular shape including a gap G. The reference potential wiring line 9 surrounds the longitudinally coupled resonator-type acoustic wave filter 6 in the substantially annular portion 9a. The substantially annular portion 9a includes a first end portion 9b and a second end portion 9c. The first end portion 9b and the second end portion 9c face each other across the gap G. The substantially annular portion 9a does not surround the longitudinally coupled resonator-type acoustic wave filter 6 only in the portion where the gap G is located. That is, the substantially annular portion 9a has a shape surrounding the longitudinally coupled resonator-type acoustic wave filter 6 when the gap G is connected.

FIG. 4 is a schematic view showing the longitudinally coupled resonator-type acoustic wave filter, and wiring lines and the reference potential wiring line that are connected to the longitudinally coupled resonator-type acoustic wave filter, according to the first example embodiment. Note that FIG. 4 corresponds to a plan view. In FIG. 4, the plurality of IDT electrodes and the pair of reflectors in the longitudinally coupled resonator-type acoustic wave filter 6 are each shown by an individual schematic diagram. Specifically, the schematic diagram is obtained by adding two diagonals to a rectangle. In FIG. 4, the wiring lines connected to the signal potential and the wiring lines connected to the reference potential are shown with mutually different hatchings.

Hereinafter, the direction in which the plurality of electrode fingers of the IDT electrode extend is defined as a first direction y, and one direction in the first direction y is defined as a +direction in the first direction y, and the other direction in the first direction y is defined as a −direction in the first direction y. The direction perpendicular to the first direction y is defined as a second direction x, and one direction in the second direction x is defined as a +direction in the second direction x, and the other direction in the second direction x is defined as a −direction in the second direction x. In FIG. 4, the +direction in the first direction y is the upper direction in FIG. 4, but the lower direction in FIG. 4 may alternatively be the +direction in the first direction y. In FIG. 4, the +direction in the second direction x is the right direction in FIG. 4, but the left direction in FIG. 4 may alternatively be the +direction in the second direction x.

The substantially annular portion 9a of the reference potential wiring line 9 has a C-shape. The substantially annular portion 9a is a path by which the reference potential wiring line 9 surrounds both sides of the +direction and the −direction in the second direction x of the longitudinally coupled resonator-type acoustic wave filter 6, a path by which the reference potential wiring line 9 surrounds a side of the −direction in the first direction y of the longitudinally coupled resonator-type acoustic wave filter 6, and a path by which the reference potential wiring line 9 surrounds a side of the +direction in the first direction y of the longitudinally coupled resonator-type acoustic wave filter 6, excluding the gap G.

The substantially annular portion 9a of the reference potential wiring line 9 is connected to one busbar of each IDT electrode of the longitudinally coupled resonator-type acoustic wave filter 6. Therefore, one busbar of each IDT electrode is connected to the reference potential via the reference potential wiring line 9 and the reference potential terminal 5 shown in FIG. 2. Therefore, when the composite filter device 10 is operated, a current flows from one busbar of each IDT electrode to the reference potential wiring line 9. Further, the current flows from the reference potential wiring line 9 to the reference potential terminal 5.

The substantially annular portion 9a of the reference potential wiring line 9 has a reference potential connection portion 9d. Specifically, the reference potential connection portion 9d is a portion extending linearly with the first end portion 9b as a starting point. Therefore, the reference potential connection portion 9d has the first end portion 9b, as one end portion, and the other end portion. However, the other end portion described above is provided integrally with other portions of the reference potential wiring line 9.

One busbar of each of some IDT electrodes of the longitudinally coupled resonator-type acoustic wave filter 6 is connected to the reference potential terminal 5 shown in FIG. 2 via a portion of the reference potential wiring line 9 including the reference potential connection portion 9d. Therefore, the current flows from the busbar to the reference potential terminal 5 via the reference potential connection portion 9d. At this time, the current flows in a direction indicated by the arrow A in FIG. 3 through the reference potential connection portion 9d. One busbar of each of the other IDT electrodes of the longitudinally coupled resonator-type acoustic wave filter 6 is connected to the reference potential terminal 5 via a portion of the reference potential wiring line 9 not including the reference potential connection portion 9d.

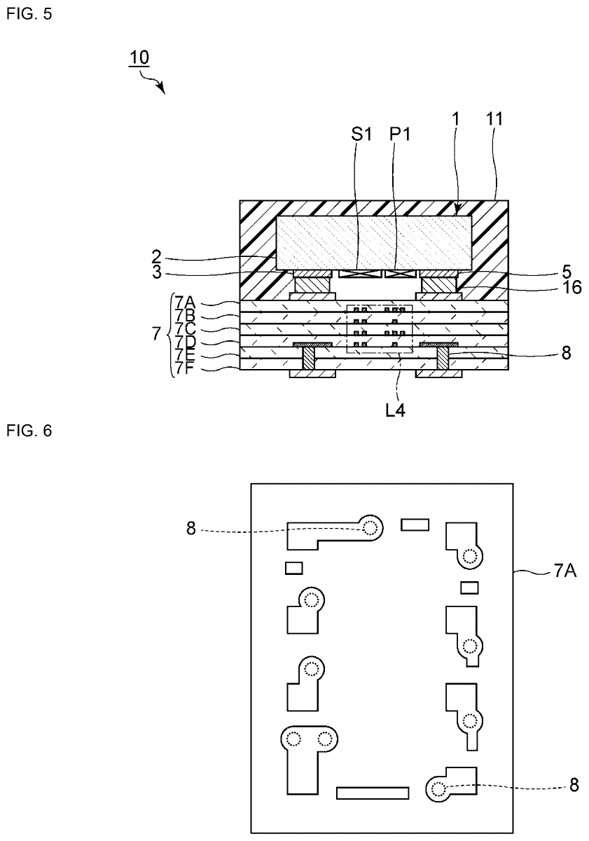

FIG. 5 is a schematic front sectional view of the composite filter device according to the first example embodiment. FIG. 5 is a schematic sectional view showing a portion taken along line I-I in FIG. 2.

The composite filter device 10 includes a mounting substrate 7. The acoustic wave element chip 1 is flip-chip mounted on the mounting substrate 7. The mounting substrate 7 is multilayer substrate including six layers. More specifically, in the mounting substrate 7, a first layer 7A, a second layer 7B, a third layer 7C, a fourth layer 7D, a fifth layer 7E, and a sixth layer 7F are laminated in this order. Among the plurality of layers, the first layer 7A is positioned closest to the piezoelectric substrate 2. In the present example embodiment, each layer of the mounting substrate 7 is a dielectric layer. However, any suitable ceramic or the like may be used for each layer. Note that the number of layers of the mounting substrate 7 is not limited to six.

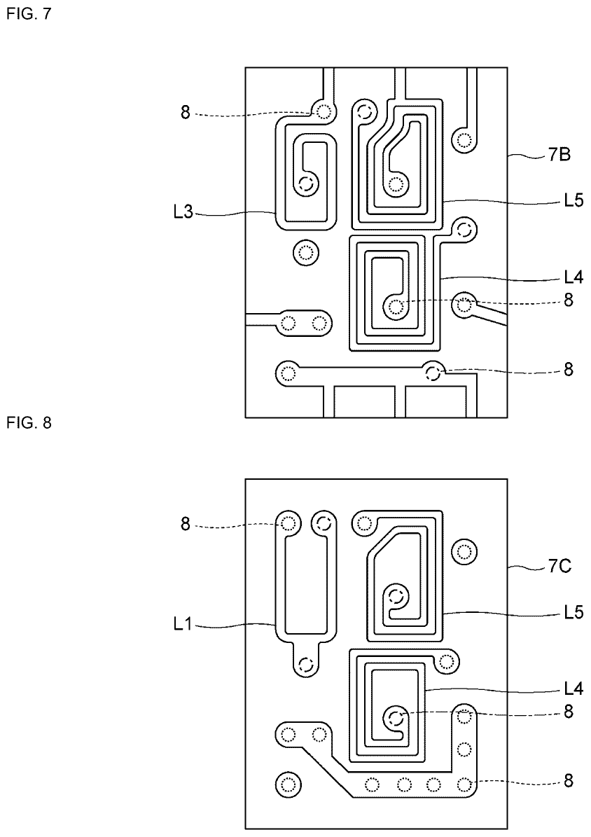

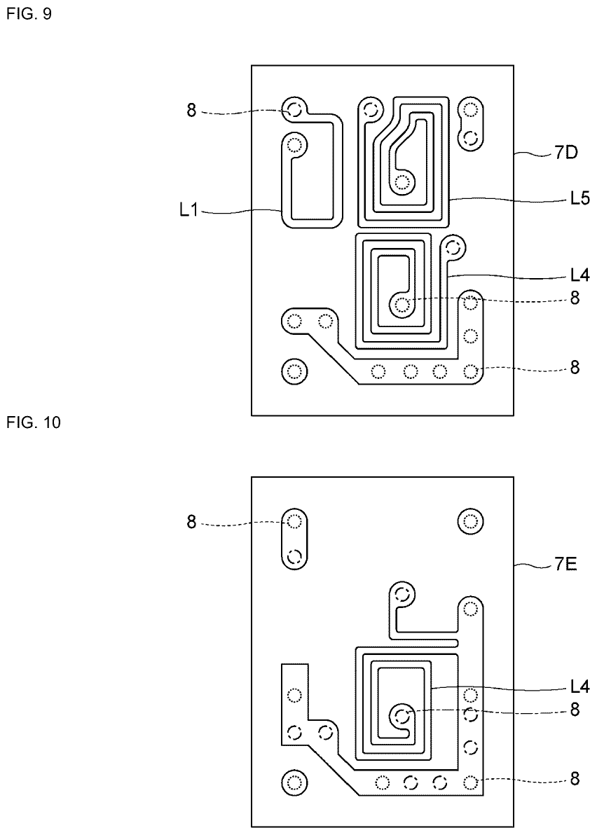

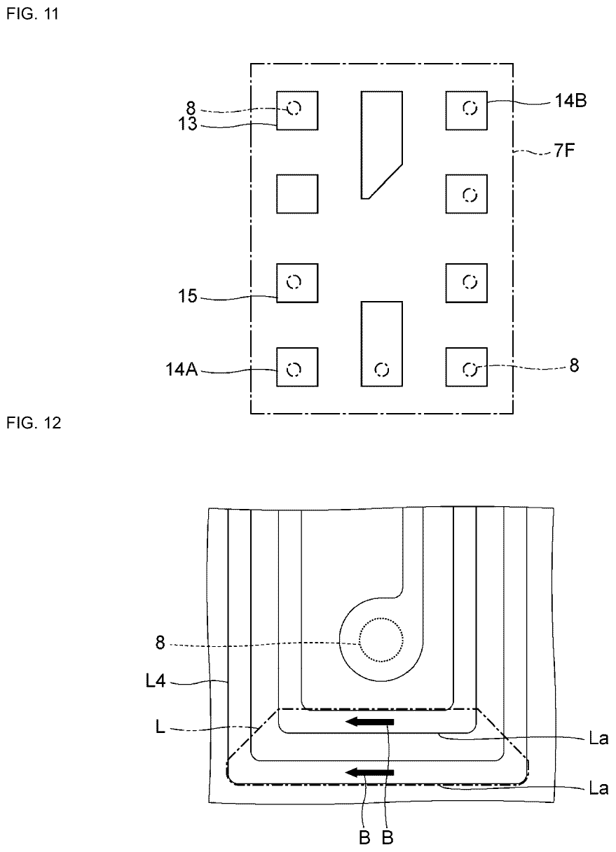

FIG. 6 is a plan view showing an electrode structure of the first layer of the mounting substrate according to the first example embodiment. FIG. 7 is a plan view showing an electrode structure of the second layer of the mounting substrate according to the first example embodiment. FIG. 8 is a plan view showing an electrode structure of the third layer of the mounting substrate according to the first example embodiment. FIG. 9 is a plan view showing an electrode structure of the fourth layer of the mounting substrate according to the first example embodiment. FIG. 10 is a plan view showing an electrode structure of the fifth layer of the mounting substrate according to the first example embodiment. FIG. 11 is a transparent plan view showing an electrode structure of the sixth layer of the mounting substrate according to the first example embodiment.

As shown in FIGS. 6 to 11, wiring electrodes are provided in each layer of the mounting substrate 7. A plurality of through-electrodes 8 are provided in the mounting substrate 7. The wiring electrodes of each layer are electrically connected to each other by the through-electrodes 8. Some of the plurality of wiring electrodes constitute respective inductors of the first filter 1A and the second filter 1B. For example, as shown in FIGS. 7 to 10, the inductor L4 of the second filter 1B is provided over the second layer 7B, the third layer 7C, the fourth layer 7D, and the fifth layer 7E. Thus, the inductor L4 is configured as a coil-shaped inductor.

Among the layers on which the inductor L4 is provided, the layer closest to the acoustic wave element chip 1 is the second layer 7B. In the present example embodiment, the wiring portion provided on the second layer 7B of the inductor L4 has a spiral shape. Such a wiring portion includes a plurality of linear portions. These linear portions include parallel wiring portions La. Specifically, the parallel wiring portions La are portions extending in parallel with the reference potential connection portion 9d shown in FIG. 3 in plan view. In the present specification, the term “plan view” means that the composite filter device 10 is viewed from a direction corresponding to the upper side to a direction corresponding to the lower side in FIG. 5. On the other hand, the term “bottom view” means that the composite filter device 10 is viewed from a direction corresponding to the lower side to a direction corresponding to the upper side in FIG. 5. Note that, as directions in FIG. 5, in the piezoelectric substrate 2 and the mounting substrate 7, the side of the piezoelectric substrate 2 is defined as an upper side, and the side of the mounting substrate 7 is defined as a lower side.

FIG. 12 is an enlarged plan view showing a portion of the inductor of the second filter provided on the second layer of the mounting substrate according to the first example embodiment.

In the present example embodiment, the wiring portion provided on the second layer 7B of the inductor L4 includes two parallel wiring portions La. The two parallel wiring portions La are arranged in a direction perpendicular to the direction in which each parallel wiring portion La extends. In the present specification, the direction perpendicular to the direction in which the parallel wiring portions La extend is a direction parallel to the main surface of the layer on which the parallel wiring portions La are provided in the mounting substrate 7. In other words, the two parallel wiring portions La are arranged in a direction perpendicular to the direction in which the reference potential connection portion 9d shown in FIG. 3 extends in plan view.

The current flows in the same direction through each of the parallel wiring portions La. Specifically, the current flows in a direction indicated by the arrow B in FIG. 12 through each of the parallel wiring portions La.

More specifically, as shown in FIG. 1, the inductor L4 is the inductor included in a parallel arm. The direction in which the current flows through such an inductor is a direction from a series arm side toward the reference potential side. In other words, the direction in which the current flows through the inductor is a direction from the signal potential side toward the reference potential side. The current flows, in a spiral manner, through the inductor L4, in which the direction in which the current flows through the parallel wiring portion La is indicated by the arrow B. On the other hand, the direction in which the current flows through the inductor included in the series arm, such as the inductor L3, is a direction from the input end side toward the output end side of the series arm.

The number of the parallel wiring portions La is not limited to two. It is sufficient that the inductor L4 includes one parallel wiring portion La, or two or more parallel wiring portions La. When the inductor L4 has two or more parallel wiring portions La, it is sufficient that the two or more parallel wiring portions La are arranged in a direction perpendicular to the direction in which the reference potential connection portion 9d shown in FIG. 3 extends in plan view. Further, the current flows in the same direction through each of the parallel wiring portions La.

As shown in FIG. 7, the inductor L4 includes wiring portions other than the parallel wiring portions La extending in parallel with the direction in which the parallel wiring portions La extend. However, the direction in which the current flows through such wiring portions is opposite to the direction in which the current flows through the parallel wiring portions La.

As shown in FIG. 12, a region including an area from the parallel wiring portion La positioned on a side closest to one side in the direction perpendicular to the direction in which the parallel wiring portions La extend to the parallel wiring portion La positioned on a side closest to the other side in the direction perpendicular to the direction in which the parallel wiring portions La extend is defined as a parallel wiring portion region L. More specifically, in the present example embodiment, the parallel wiring portion region L includes regions where two parallel wiring portions La are provided and a region between adjacent parallel wiring portions La. One edge portion of the parallel wiring portion region L in the direction in which the parallel wiring portions La extend is a virtual line connecting one end portions of the parallel wiring portions La. The other edge portion of the parallel wiring portion region L in the direction in which the parallel wiring portions La extend is a virtual line connecting the other end portions of the parallel wiring portions La.

When the inductor L4 includes three or more parallel wiring portions La, the parallel wiring portion region L also includes regions where respective parallel wiring portions La are provided and regions between adjacent parallel wiring portions La. On the other hand, when the inductor L4 includes only one parallel wiring portion La, the parallel wiring portion region L includes only a region where the parallel wiring portion La is provided.

All of the parallel wiring portions La are provided on the second layer 7B, which is the layer closest to the acoustic wave element chip 1, among the layers on which the inductor L4 is provided. The parallel wiring portion region L is a region defined by the configuration of one or two or more parallel wiring portions La provided on the second layer 7B.

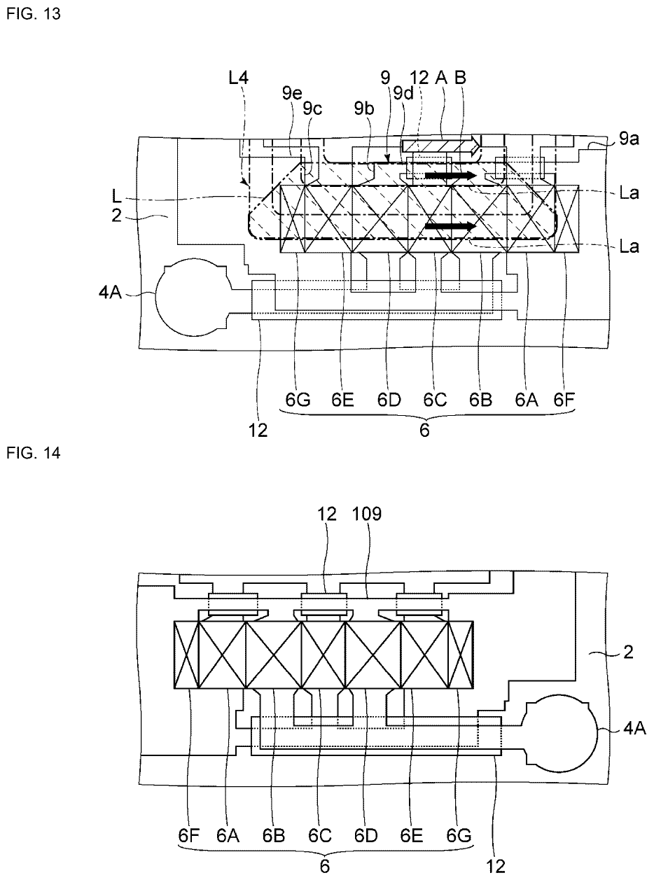

FIG. 13 is a schematic bottom view showing the positional relationship between the reference potential wiring line and the inductors of the second filter in the first example embodiment. The view shown in FIG. 13, which is a bottom view, is shown in a left-right reversed manner from the plan view shown in FIG. 3 and the like. In FIG. 13, the plurality of IDT electrodes and the pair of reflectors in the longitudinally coupled resonator-type acoustic wave filter 6 are each shown by an individual schematic diagram. Specifically, the schematic diagram is obtained by adding two diagonals to a rectangle. In FIG. 13, among the plurality of inductors of the second filter 1B, only the inductor L4 is indicated by a dash-dotted line. More specifically, in FIG. 13, only the wiring portion of the inductor L4 provided on the second layer is indicated. In FIG. 13, the parallel wiring portion region L is hatched.

The parallel wiring portion region L and the reference potential connection portion 9d overlap with each other in plan view and bottom view. Further, each of the parallel wiring portions La extends in parallel or substantially in parallel with the reference potential connection portion 9d in plan view. Note that, in the present specification, it is assumed that the reference potential connection portion 9d and the parallel wiring portion La are parallel to each other when the absolute value of the angle defined between the reference potential connection portion 9d and the parallel wiring portion La is about 15° or less in plan view, for example.

The current flows in a direction indicated by the arrow B in FIG. 13 through the parallel wiring portion La of the inductor L4. The direction of the current flowing through the parallel wiring portion La is a direction toward a reference potential electrode described later. On the other hand, the current flows in a direction indicated by the arrow A through the reference potential connection portion 9d of the reference potential wiring line 9. The direction of the current flowing through the reference potential connection portion 9d is a direction from the longitudinally coupled resonator-type acoustic wave filter 6 toward the reference potential terminal.

In the present specification, it is assumed that the direction of the current flowing through the reference potential connection portion 9d is parallel to the direction in which the reference potential connection portion 9d extends. Similarly, it is assumed that the direction of the current flowing through the parallel wiring portion La is parallel to the direction in which the parallel wiring portion La extends. That is, in the present specification, it is assumed that the direction of the current flowing through the reference potential connection portion 9d and the direction of the current flowing through the parallel wiring portion La are parallel to each other when the absolute value of the angle defined between the reference potential connection portion 9d and the parallel wiring portion La is about 15° or less in plan view, for example. However, it is preferable that the absolute value of the angle defined between the reference potential connection portion 9d and the parallel wiring portion La is about 15° or less, for example.

A feature of the present example embodiment is that the reference potential wiring line 9 includes the substantially annular portion 9a, the substantially annular portion 9a includes the reference potential connection portion 9d, the parallel wiring portion region L and the reference potential connection portion 9d overlap with each other in plan view, and the direction of the current flowing through the parallel wiring portion La of the inductor L4 and the direction of the current flowing through the reference potential connection portion 9d are the same. Thus, the out-band attenuation of the first filter 1A, which is a band pass filter, can be increased. The details are explained by comparing the present example embodiment with a first comparative example.

The first comparative example differs from the first example embodiment in that a reference potential wiring line 109 completely surrounds the longitudinally coupled resonator-type acoustic wave filter 6, as shown in FIG. 14. The attenuation-frequency characteristics of the first filter and the second filter were measured for the respective composite filter devices of the first example embodiment and the first comparative example.

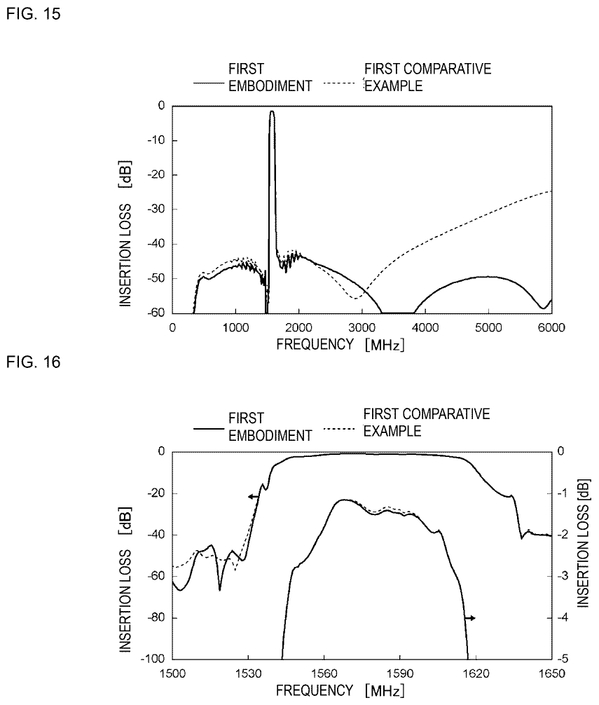

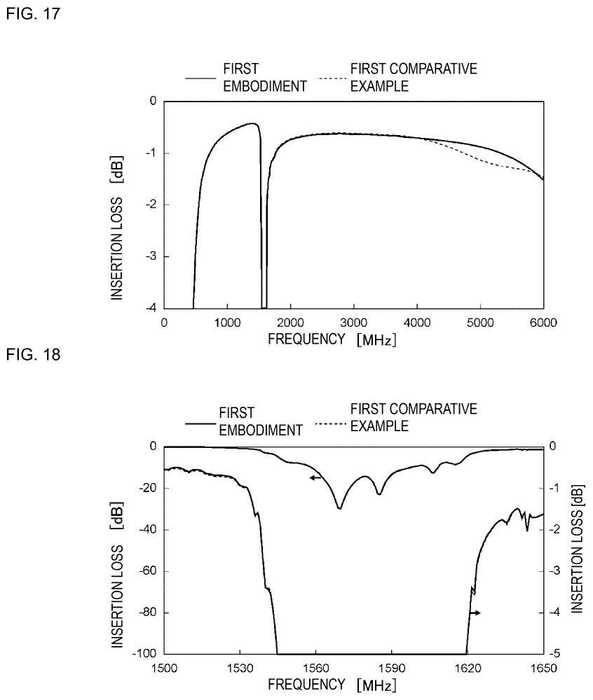

FIG. 15 is a graph showing the attenuation-frequency characteristics of the first filter in the first example embodiment and the attenuation-frequency characteristics of the first filter in the first comparative example, in a wide frequency range. FIG. 16 is a graph showing the attenuation-frequency characteristics of the first filter in the first example embodiment and the attenuation-frequency characteristics of the first filter in the first comparative example, in the vicinity of the pass band. FIG. 17 is a graph showing the attenuation-frequency characteristics of the second filter in the first example embodiment and the attenuation-frequency characteristics of the second filter in the first comparative example, in a wide frequency range. FIG. 18 is a graph showing the attenuation-frequency characteristics of the second filter in the first example embodiment and the attenuation-frequency characteristics of the second filter in the first comparative example, in the vicinity of the attenuation band.

It is known that, as shown in FIG. 15, the out-band attenuation is larger in the first example embodiment than in the first comparative example. In the first example embodiment, the attenuation on both the high-frequency side and the low-frequency side is larger in the vicinity of the pass band. Further, it is known that the attenuation is significantly larger in a frequency range that exceeds twice the frequency at the center of the pass band. Note that, as shown in FIG. 16, there is no significant difference in the insertion loss in the pass band between the first example embodiment and the first comparative example. As shown in FIGS. 17 and 18, there is no significant difference in the attenuation-frequency characteristics of the second filter between the first example embodiment and the first comparative example.

In the first example embodiment, the reason why the out-band attenuation of the first filter 1A, which is a band pass filter, can be increased is as follows. When a current flows through the inductor L4 shown in FIG. 13, a magnetic field is generated. In the first example embodiment, since the parallel wiring portion region L and the reference potential connection portion 9d overlap with each other in plan view, the magnetic field passes through the reference potential connection portion 9d of the reference potential wiring line 9. Further, the direction of the current flowing through the parallel wiring portion La of the inductor L4 and the direction of the current flowing through the reference potential connection portion 9d are the same. Thus, the electromagnetic coupling between the inductor L4 and the longitudinally coupled resonator-type acoustic wave filter 6 is enhanced. Thus, the out-band attenuation of the first filter 1A can be increased.

As shown in FIG. 3, in the first example embodiment, the reference potential wiring line 9 has the substantially annular portion 9a, and the substantially annular portion 9a has the reference potential connection portion 9d. Thus, the current flows in a fixed direction through the reference potential connection portion 9d. More specifically, the first end portion 9b, as one end portion of the reference potential connection portion 9d, faces the gap G. The other end portion of the reference potential connection portion 9d is connected to the reference potential terminal 5 shown in FIG. 2 via other portions of the reference potential wiring line 9. Therefore, the current flows through the reference potential connection portion 9d from the side of the first end portion 9b, as one end portion, to the side of the other end portion. Thus, the direction of the current flowing through the parallel wiring portion La of the inductor L4 and the direction of the current flowing through the reference potential connection portion 9d can be made the same.

On the other hand, in the first comparative example, as shown in FIG. 14, the reference potential wiring line 109 completely surrounds the longitudinally coupled resonator-type acoustic wave filter 6 in the portion of the annular shape. Therefore, it is difficult to make the current flow in a fixed direction through the reference potential wiring line 109.

Referring back to FIG. 13, in an example embodiment of the present invention, it is sufficient that the parallel wiring portion region L and the reference potential connection portion 9d overlap with each other in plan view. More specifically, the parallel wiring portions La of the inductor L4 and the reference potential connection portion 9d may overlap with each other in plan view. Alternatively, the portion between the adjacent parallel wiring portions La and the reference potential connection portion 9d may overlap with each other in plan view. In any of such cases, there is no significant difference in the influence of the magnetic field in the portion where the parallel wiring portion region L and the reference potential connection portion 9d overlap with each other in plan view. Therefore, even when the parallel wiring portion La and the reference potential connection portion 9d do not overlap with each other in plan view, the out-band attenuation of the first filter 1A, which is a band pass filter, can be increased as in the first example embodiment.

The configuration of the first example embodiment will be described in more detail below.

As shown in FIG. 3, the longitudinally coupled resonator-type acoustic wave filter 6 includes a plurality of IDT electrodes and a pair of reflectors. Specifically, the plurality of IDT electrodes are an IDT electrode 6A, an IDT electrode 6B, an IDT electrode 6C, an IDT electrode 6D, and an IDT electrode 6E. The pair of reflectors are a reflector 6F and a reflector 6G. By applying an AC voltage to each IDT electrode, an acoustic wave is excited. The IDT electrode 6A, the IDT electrode 6B, the IDT electrode 6C, the IDT electrode 6D, and the IDT electrode 6E are arranged in this order in an acoustic wave propagation direction. Further, the pair of reflectors 6F and 6G are provided so as to sandwich the five IDT electrodes in the acoustic wave propagation direction. The acoustic wave propagation direction is parallel to the second direction x.

The number of IDT electrodes of the longitudinally coupled resonator-type acoustic wave filter 6 is not limited to five. The number of IDT electrodes may alternatively be three, seven, or nine, for example. In the first example embodiment, the longitudinally coupled resonator-type acoustic wave filter 6 has a one stage configuration. However, the longitudinally coupled resonator-type acoustic wave filter 6 may include a plurality of stages. In such a case, it is sufficient that a plurality of IDT electrodes and a pair of reflectors are provided in each stage.

As shown in FIG. 3, each IDT electrode includes a pair of busbars and a plurality of electrode fingers. Specifically, for example, the IDT electrode 6A includes a first busbar 18A and a second busbar 18B, a plurality of first electrode fingers 19A and a plurality of second electrode fingers 19B. The first busbar 18A and the second busbar 18B face each other. One end of each of the plurality of first electrode fingers 19A is connected to the first busbar 18A. One end of each of the plurality of second electrode fingers 19B is connected to the second busbar 18B. The plurality of first electrode fingers 19A and the plurality of second electrode fingers 19B are interdigitated with each other. The same goes for other IDT electrodes.

In the present specification, the first busbar 18A and the second busbar 18B may be collectively referred to simply as a busbar. The first electrode fingers 19A and the second electrode fingers 19B may be collectively referred to simply as electrode fingers.

Each of the reflector 6F and the reflector 6G includes a plurality of reflector electrode fingers 17. In the first example embodiment, a portion of each reflector is provided integrally with the reference potential wiring line 9. In FIG. 3, the outer shapes of the reflector 6F and the reflector 6G are shown by dash-dotted lines for convenience. Each reflector is connected to the reference potential. However, each reflector does not have to be connected to the reference potential.

Each IDT electrode and each reflector may include a laminated metal film, or may include a single-layer metal film.

As described above, the reference potential connection portion 9d includes the first end portion 9b, as one end portion, and the other end portion. When viewed from the first direction y, the other end portion described above overlaps with an edge portion of the reflector electrode fingers 17, in the reflector 6F, farthest from the first end portion 9b. However, the other end portion described above is provided integrally with other portions of the reference potential wiring line 9.

As shown in FIGS. 3 and 4, the substantially annular portion 9a of the reference potential wiring line 9 has an opposing portion 9e. Specifically, the opposing portion 9e is a portion facing the reference potential connection portion 9d across the gap G. The opposing portion 9e includes the second end portion 9c, as one end portion, and the other end portion. When viewed from the first direction y, the other end portion described above overlaps with an edge portion of the reflector electrode fingers 17, in the reflector 6G, farthest from the second end portion 9c. However, the other end portion described above is provided integrally with other portions of the reference potential wiring line 9. The opposing portion 9e extends with the second end portion 9c as a starting point, and is connected to the reference potential.

Here, the length of the reference potential connection portion 9d is M1, and the length of the opposing portion 9e is M2. The length M1 is a distance between the first end portion 9b, as one end portion of the reference potential connection portion 9d, and the other end portion when viewed from the first direction y. Similarly, the length M2 is a distance between the second end portion 9c, as one end portion of the opposing portion 9e, and the other end portion when viewed from the first direction y.

The length M1 of the reference potential connection portion 9d is longer than the length M2 of the opposing portion 9e. Thus, it can be considered that the current flows in the direction of the arrow A as a whole of the reference potential connection portion 9d and the opposing portion 9e. As shown by the arrow B in FIG. 13, the direction of the current flowing through the parallel wiring portions La of the inductor L4 is the same as the direction of the arrow A. Thus, the electromagnetic coupling between the inductor L4 and the longitudinally coupled resonator-type acoustic wave filter 6 can be enhanced, and the out-band attenuation of the first filter 1A can be increased.

As shown in FIG. 3, an insulating film 12 is laminated on a portion of the substantially annular portion 9a of the reference potential wiring line 9. The substantially annular portion 9a and the wiring line connected to the signal potential face each other with the insulating film 12 sandwiched therebetween. The reference potential wiring line 9 and the wiring line connected to the signal potential are electrically insulated by the insulating film 12.

A plurality of wiring lines connected to the reference potential are provided on the piezoelectric substrate 2. The reference potential wiring line 9 is provided integrally with another wiring line. The reference potential wiring line 9 is a wiring line including at least the substantially annular portion 9a.

In the first example embodiment, a wiring line connected to the signal potential passes through the gap G. Such a wiring line is connected to one busbar of the IDT electrode 6E. Among the plurality of IDT electrodes of the longitudinally coupled resonator-type acoustic wave filter 6, the IDT electrode 6E is an IDT electrode positioned closest to the reflector 6G. Here, the reflector positioned closer to the reference potential connection portion 9d side, among the reference potential connection portion 9d side and the opposing portion 9e side, is a first reflector, and the reflector positioned closer to the opposing portion 9e side is a second reflector. The reflector 6F is the first reflector. The reflector 6G is the second reflector. The IDT electrode 6E is adjacent to the second reflector.

Note that the position of the gap G is not limited to the position described above. It is sufficient that the gap G is arranged so that the length M1 of the reference potential connection portion 9d is longer than the length M2 of the opposing portion 9e. It is preferable that, among the plurality of IDT electrodes of the longitudinally coupled resonator-type acoustic wave filter 6, an IDT electrode positioned closer to the second reflector than to the first reflector overlaps with the gap G when viewed from the electrode finger extending direction. It is further preferable that, among the plurality of IDT electrodes, the IDT electrode 6E positioned closest to the second reflector overlaps with the gap G when viewed from the electrode finger extending direction. Thus, the length M1 of the reference potential connection portion 9d can be increased more reliably.

Alternatively, it is preferable that, among the plurality of IDT electrodes of the longitudinally coupled resonator-type acoustic wave filter 6, the number of IDT electrodes connected to the reference potential connection portion 9d is larger than the number of IDT electrodes connected to the opposing portion 9e. For example, in the present example embodiment, the IDT electrode 6B and the IDT electrode 6D are connected to the reference potential connection portion 9d. On the other hand, no IDT electrode is connected to the opposing portion 9e. In such a case, the length M1 of the reference potential connection portion 9d can be increased more reliably.

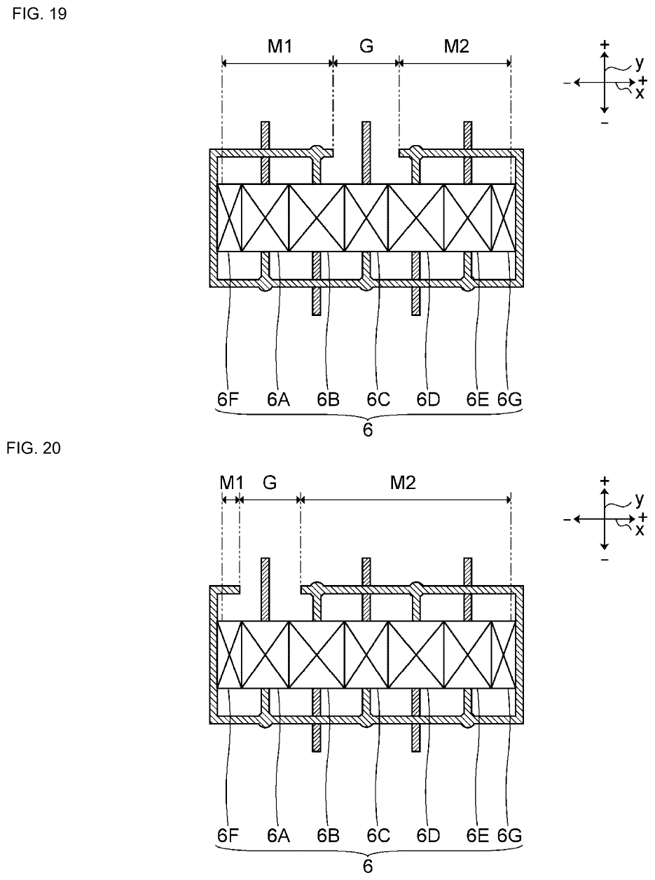

On the other hand, even if the reference potential wiring line includes a substantially annular portion, an advantageous effect of an example embodiment of the present invention cannot be obtained when M1≤M2. For example, in a second comparative example shown in FIG. 19, when viewed from the first direction y, the gap G overlaps with, among the plurality of IDT electrodes of the longitudinally coupled resonator-type acoustic wave filter 6, the IDT electrode 6C located in a central position. In such a case, M1=M2.

In a third comparative example shown in FIG. 20, when viewed from the first direction y, the gap G overlaps with, among the plurality of IDT electrodes of the longitudinally coupled resonator-type acoustic wave filter 6, the IDT electrode 6A closest to the reflector 6F. In such a case, M1<M2.

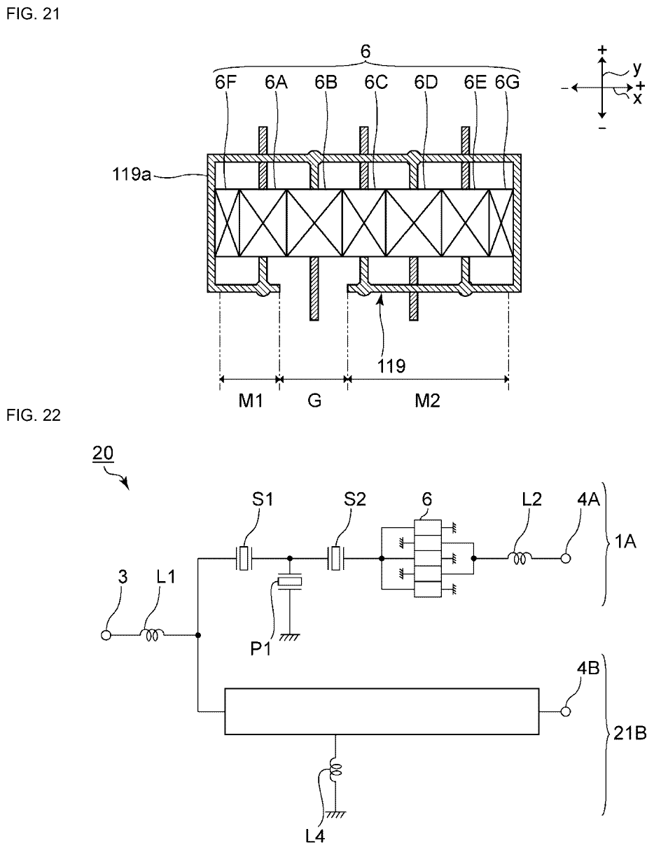

In a fourth comparative example shown in FIG. 21, when viewed from the first direction y, the gap G overlaps with, among the plurality of IDT electrodes of the longitudinally coupled resonator-type acoustic wave filter 6, the IDT electrode 6B closer to the reflector 6F than to the reflector 6G. In a substantially annular portion 119a of a reference potential wiring line 119, the gap G is provided in the −direction in the first direction y with respect to the longitudinally coupled resonator-type acoustic wave filter 6. In such a case, M1<M2.

Each of the acoustic wave resonators shown in FIG. 1 includes one IDT electrode and one pair of reflectors. The pair of reflectors sandwich the IDT electrode in the acoustic wave propagation direction.

As shown in FIG. 5, the acoustic wave element chip 1 is flip-chip mounted on the mounting substrate 7. More specifically, the respective terminals provided on the piezoelectric substrate 2 are joined to the respective terminals provided on the first layer 7A of the mounting substrate 7 by bumps 16. Further, a sealing resin layer 11 is provided on the mounting substrate 7 so as to cover the acoustic wave element chip 1.

As shown in FIG. 2, the respective resonators of the first filter 1A including the longitudinally coupled resonator-type acoustic wave filter 6 and the respective resonators of the second filter 1B are configured on the same piezoelectric substrate 2. However, the respective resonators of the first filter 1A and the respective resonators of the second filter 1B may alternatively be configured on different piezoelectric substrates from each other. Therefore, an acoustic wave element chip in which the first filter 1A is configured and an acoustic wave element chip in which the second filter 1B is configured may be mounted on the mounting substrate 7.

The composite filter device 10 of the first example embodiment preferably has a chip size package (CSP) structure, for example. However, the composite filter device 10 of the first example embodiment does not have to have a CSP structure. For example, the composite filter device may have a wafer level package (WLP) structure. When the composite filter device has a WLP structure, it is sufficient that the acoustic wave element chip is configured to have a hollow space. The plurality of IDT electrodes are preferably provided in the hollow space. It is sufficient that the acoustic wave element chip is mounted on, for example, the mounting substrate 7 shown in FIG. 5. The sealing resin layer 11 may be provided on the mounting substrate 7 so as to cover the acoustic wave element chip.

Specifically, in the acoustic wave element chip, for example, a support is provided on a piezoelectric substrate so as to surround the plurality of IDT electrodes. The support has a cavity. The plurality of IDT electrodes are positioned in the cavity. A cover is provided so as to cover the cavity of the support. The plurality of IDT electrodes are disposed in a hollow space surrounded by the piezoelectric substrate, the support, and the cover. A plurality of through-electrodes are provided so as to pass through the cover and the support. One end of each through-electrode is connected to a corresponding one of the terminals on the piezoelectric substrate. In such a manner, an acoustic wave element chip is provided. A bump is joined to the other end of each through-electrode. The acoustic wave element chip is mounted on the mounting substrate by using a plurality of bumps.

As shown in FIG. 5, in the first example embodiment, the inductor L4 is provided from the second layer 7B to the fifth layer 7E of the mounting substrate 7. More specifically, as shown in FIG. 7, the inductor L4 includes a wiring portion. The wiring portion has a spiral shape. The wiring portion includes a plurality of portions extending linearly. The through-electrode 8 is connected to the end portion of the wiring portion. The wiring portions of the inductor L4 shown in FIGS. 7 to 10 are connected to each other by the through-electrode 8. Therefore, the inductor L4 includes a plurality of through-electrodes 8. The plurality of wiring portions and the plurality of through-electrodes 8 define a coil-shaped inductor L4.

However, the shape of the wiring portion of each layer of the inductor L4 is not limited to the shape described above. For example, the wiring portion provided on, among the layers on which the inductor L4 is provided, the layer closest to the acoustic wave element chip 1 may be a linear shape, an L-shape, a curved shape that does not circle around, or the like. In such cases, it is sufficient that the inductor L4 includes one of the parallel wiring portions La. The shape of the wiring portion of each of the other layers may also be, for example, a linear shape, an L-shape, or a curved shape that does not circle around. It is preferable that the inductor L4 is a coil-shaped inductor by connecting the wiring portion of each layer.

One end of the inductor L4 is electrically connected to the reference potential terminal 5 via an electrode pad provided on the first layer 7A and the bump 16 shown in FIG. 5. The other end of the inductor L4 is connected to an external reference potential. More specifically, as shown in FIG. 11, a reference potential electrode 15 is provided on the sixth layer 7F. The inductor L4 is connected to the reference potential via the reference potential electrode 15. Therefore, the direction of the current flowing through the inductor L4 is a direction toward the reference potential electrode 15. As described above, the direction of the current flowing through the parallel wiring portion La shown in FIG. 13 is a direction toward the reference potential electrode 15.

A common connection electrode 13, a first signal electrode 14A, and a second signal electrode 14B are provided on the sixth layer 7F. The common connection electrode 13 is electrically connected to the two common connection terminals 3 on the piezoelectric substrate 2 via the respective wiring lines and the through-electrodes 8 in the mounting substrate 7, and the bumps 16. That is, the two common connection terminals 3 are shared in the mounting substrate 7. Similarly, the first signal electrode 14A is electrically connected to the first signal terminal 4A. The second signal electrode 14B is electrically connected to the second signal terminal 4B.

In the first example embodiment, no wiring line connected to a reference electrode is provided between the reference potential connection portion 9d and the inductor L4. Thus, the out-band attenuation of the first filter 1A can be effectively increased.

A portion of the wiring portion of the inductor L4 is provided on the second layer 7B. More specifically, a portion of the wiring portion of the inductor L4 is provided between the first layer 7A and the second layer 7B. Thus, the distance between the reference potential connection portion 9d and the inductor L4 can be reduced. Thus, the effect obtained by making the direction of the current flowing through the parallel wiring portion La of the inductor L4 and the direction of the current flowing through the reference potential connection portion 9d the same direction can be increased. That is, the electromagnetic coupling between the longitudinally coupled resonator-type acoustic wave filter 6 and the inductor L4 can be further enhanced. Therefore, the out-band attenuation of the first filter 1A can be further increased.

Note that the wiring structure of the mounting substrate 7 is not limited to the wiring structure described above. However, it is preferable that the reference potential connection portion 9d and the inductor L4 face each other with no wiring line connected to the reference potential provided therebetween. It is preferable that at least a portion of the wiring portion of the inductor L4 is provided at a position on the piezoelectric substrate 2 side with respect to the center in the thickness direction of the mounting substrate 7. It is further preferable that at least a portion of the wiring portion of the inductor L4 is provided in, among a plurality of interlayer portions of the mounting substrate 7, a portion closest to the piezoelectric substrate 2. Thus, as described above, the out-band attenuation of the first filter 1A can be further increased.

The pass band of the first filter 1A and the attenuation band of the second filter 1B are in the same frequency range. Thus, the out-band attenuation of the first filter 1A can be effectively increased. However, the pass band of the first filter 1A and the attenuation band of the second filter 1B may be in frequency ranges different from each other.

As in the first example embodiment, it is preferable that the inductor L4 is configured so that the magnetic field generated when a current flows through the inductor L4 is directed from the piezoelectric substrate 2 side to the mounting substrate 7 side. In such a case, the out-band attenuation of the first filter 1A can be effectively increased.

In the first example embodiment, the inductor L4, as a parallel inductor, overlaps with the longitudinally coupled resonator-type acoustic wave filter 6 in plan view. However, the inductor L3, as a series inductor, in the second filter 1B may overlap with the reference potential connection portion 9d in plan view. In such a case, the inductor L3 may have a parallel wiring portion, and have a parallel wiring portion region. The parallel wiring portion region of the inductor L3 and the reference potential connection portion 9d may overlap with each other in plan view. It is sufficient that the direction of the current flowing through the parallel wiring portion and the direction of the current flowing through the reference potential connection portion 9d are the same.

As described above, the composite filter device 10 is an extractor, for example. However, the composite filter device 10 does not have to be an extractor. For example, in a modification of the first example embodiment schematically shown in FIG. 22, a second filter 21B is a band pass filter. The circuit configuration of the second filter 21B is not particularly limited except that it has at least one resonator and has the same inductor L4 as in the first example embodiment. In a composite filter device 20 of the present modification, both the first filter 1A and the second filter 21B are band pass filters.

In the present modification, the inductor L4 is provided as in the first example embodiment. The first filter 1A is configured in the same manner as in the first example embodiment. Therefore, in the composite filter device 20, the parallel wiring portion region and the reference potential connection portion overlap with each other in plan view, and the direction of the current flowing through the parallel wiring portion of the inductor L4 and the direction of the current flowing through the reference potential connection portion are the same. Thus, the out-band attenuation of the first filter 1A can be effectively increased.

Each of the two band pass filters of the composite filter device 20 may be a transmission filter that outputs a signal inputted from a transmission terminal to the common connection terminal 3, or a reception filter that outputs a signal inputted from the common connection terminal 3 to a reception terminal.

A second example embodiment and a third example embodiment will be described below. In the description of the second example embodiment and the third example embodiment, reference signs “L4”, “La”, and “L” of the inductor L4, the parallel wiring portion La, and the parallel wiring portion region L used in the description of the first example embodiment will be used.

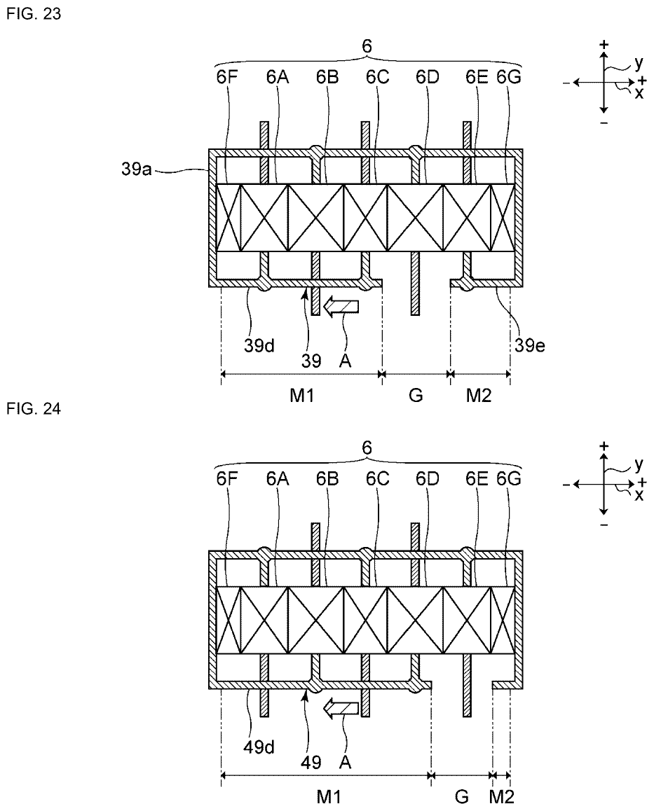

FIG. 23 is a schematic view showing a longitudinally coupled resonator-type acoustic wave filter, and wiring lines and a reference potential wiring line that are connected to the longitudinally coupled resonator-type acoustic wave filter, according to a second example embodiment.

The present example embodiment differs from the first example embodiment in the positions of a reference potential connection portion 39d, an opposing portion 39e, and a gap G in a substantially annular portion 39a of a reference potential wiring line 39. Specifically, the reference potential connection portion 39d, the opposing portion 39e, and the gap G are positioned in the −direction in the first direction y with respect to the longitudinally coupled resonator-type acoustic wave filter 6. The present example embodiment differs from the first example embodiment in the position of the inductor L4 shown in FIG. 13. Specifically, the inductor L4 is positioned so that the parallel wiring portion region L overlaps with the reference potential connection portion 39d, which is positioned in the −direction in the first direction y with respect to the longitudinally coupled resonator-type acoustic wave filter 6, in plan view. Except for the above-mentioned points, the composite filter device of the present example embodiment has the same configuration as that of the composite filter device 10 of the first example embodiment.

More specifically, the gap G overlaps with, among the plurality of IDT electrodes of the longitudinally coupled resonator-type acoustic wave filter 6, the IDT electrode 6D when viewed from the first direction y. The wiring line connected to the signal potential passes through the gap G.

The IDT electrode 6D is, among the plurality of IDT electrodes of the longitudinally coupled resonator-type acoustic wave filter 6, an IDT electrode positioned closer to the reflector 6G, as the second reflector, than to the reflector 6F, as the first reflector. The number of IDT electrodes connected to the reference potential connection portion 39d is larger than the number of IDT electrodes connected to the opposing portion 39e.

In the present example embodiment, as in the first example embodiment, M1>M2. Further, the parallel wiring portion region L and the reference potential connection portion 39d overlap with each other in plan view, and the direction of the current flowing through the parallel wiring portion La of the inductor L4 and the direction of the current flowing through the reference potential connection portion 39d are the same. Thus, the out-band attenuation of the first filter, which is a band pass filter, can be increased.

FIG. 24 is a schematic view showing a longitudinally coupled resonator-type acoustic wave filter, and wiring lines and a reference potential wiring line that are connected to the longitudinally coupled resonator-type acoustic wave filter, according to a third example embodiment.

The present example embodiment is different from the second example embodiment in the position of the gap G in a reference potential wiring line 49. The present example embodiment is also different from the second example embodiment in the potential to which the wiring line connected to each busbar of each IDT electrode in the longitudinally coupled resonator-type acoustic wave filter 6 is connected. Specifically, the wiring line that is connected to the signal potential in the second example embodiment is connected to the reference potential in the present example embodiment. On the other hand, the wiring line that is connected to the reference potential in the second example embodiment is connected to the signal potential in the present example embodiment. Except for the above-mentioned points, the composite filter device of the present example embodiment has the same configuration as that of the composite filter device of the second example embodiment.

More specifically, the gap G overlaps with, among the plurality of IDT electrodes of the longitudinally coupled resonator-type acoustic wave filter 6, the IDT electrode 6E when viewed from the first direction y. The wiring line connected to the signal potential passes through the gap G.

In the present example embodiment, as in the second example embodiment, M1>M2. Further, the parallel wiring portion region L and a reference potential connection portion 49d overlap with each other in plan view, and the direction of the current flowing through the parallel wiring portion La of the inductor L4 and the direction of the current flowing through the reference potential connection portion 49d are the same. Thus, the out-band attenuation of the first filter, which is a band pass filter, can be increased.

In the first to third example embodiments and the modification, a case where the composite filter device is an extractor and a case where the composite filter device is a duplexer have been shown, but the present invention is not limited to these cases. A composite filter device according to an example embodiment of the present invention may be a multiplexer including three or more filters including at least one band pass filter.

Example embodiments of composite filter devices according to the present invention will be collectively described below.

<1>

A composite filter device including a piezoelectric substrate, a first filter that is a band pass filter and includes a longitudinally coupled resonator-type acoustic wave filter provided on the piezoelectric substrate, a second filter that includes at least one resonator and an inductor connected to a reference potential, and a reference potential wiring line that is a wiring line provided on the piezoelectric substrate and connected to the reference potential, that has a substantially annular portion having an annular shape including a gap, and that surrounds, in the substantially annular portion, the longitudinally coupled resonator-type acoustic wave filter, wherein the substantially annular portion of the reference potential wiring line includes a first end portion and a second end portion that face each other across the gap, and a reference potential connection portion that extends with the first end portion as a starting point and that connects the longitudinally coupled resonator-type acoustic wave filter to the reference potential, the inductor includes one parallel wiring portion that extends in parallel or substantially in parallel with the reference potential connection portion in plan view, or two or more parallel wiring portions that extend in parallel or substantially in parallel with the reference potential connection portion and are arranged in a direction perpendicular to a direction in which the reference potential connection portion extends in plan view, wherein currents flowing through the two or more parallel wiring portions have a same direction, and when a region including an area from a parallel wiring portion positioned on a side closest to one side in a direction perpendicular to a direction in which the parallel wiring portion extends to a parallel wiring portion positioned on a side closest to another side in the direction perpendicular to the direction in which the parallel wiring portion extends is defined as a parallel wiring portion region, the parallel wiring portion region and the reference potential connection portion overlap with each other in plan view, and a direction of a current flowing through the parallel wiring portion and a direction of a current flowing through the reference potential connection portion are same.

<2>

The composite filter device according to <1>, wherein the substantially annular portion of the reference potential wiring line includes an opposing portion that faces the reference potential connection portion across the gap, that extends with the second end portion as a starting point, and that is connected to the reference potential, and the longitudinally coupled resonator-type acoustic wave filter includes a plurality of IDT electrodes, and among the plurality of IDT electrodes, a number of IDT electrodes of the longitudinally coupled resonator-type acoustic wave filter connected to the reference potential connection portion is larger than a number of IDT electrodes of the longitudinally coupled resonator-type acoustic wave filter connected to the opposing portion.

<3>

The composite filter device according to <1> or <2>, wherein the longitudinally coupled resonator-type acoustic wave filter of the first filter and the resonator of the second filter are both provided on the piezoelectric substrate.

<4>

The composite filter device according to any one of <1> to <3>, further including a mounting substrate which is a multilayer substrate including a plurality of layers, wherein the inductor of the second filter is provided over the plurality of layers of the mounting substrate.

<5>

The composite filter device according to any one of <1> to <4>, wherein the second filter is a band elimination filter.

<6>

The composite filter device according to <5>, wherein a pass band of the first filter and an attenuation band of the second filter have a same frequency range.

<7>

The composite filter device according to any one of <1> to <4>, wherein the second filter is a band pass filter.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A composite filter device comprising:
a piezoelectric substrate;
a first filter that is a band pass filter and that includes a longitudinally coupled resonator acoustic wave filter provided on the piezoelectric substrate;
a second filter that includes at least one resonator and an inductor connected to a reference potential; and
a reference potential wiring line that is a wiring line provided on the piezoelectric substrate and connected to the reference potential, that has a substantially annular portion having an annular shape including a gap, and that surrounds, in the substantially annular portion, the longitudinally coupled resonator acoustic wave filter; wherein
the substantially annular portion of the reference potential wiring line includes a first end portion and a second end portion that face each other across the gap, and a reference potential connection portion that extends with the first end portion as a starting point and that connects the longitudinally coupled resonator acoustic wave filter to the reference potential;
the inductor includes one parallel wiring portion that extends in parallel or substantially in parallel with the reference potential connection portion in plan view, or two or more parallel wiring portions that extend in parallel or substantially in parallel with the reference potential connection portion and are arranged in a direction perpendicular to a direction in which the reference potential connection portion extends in plan view such that currents flowing through the two or more parallel wiring portions have a same direction; and
when a region including an area from a parallel wiring portion positioned on a side closest to one side in a direction perpendicular to a direction in which the parallel wiring portion extends to a parallel wiring portion positioned on a side closest to another side in the direction perpendicular to the direction in which the parallel wiring portion extends is defined as a parallel wiring portion region, the parallel wiring portion region and the reference potential connection portion overlap with each other in plan view, and a direction of a current flowing through the parallel wiring portion and a direction of a current flowing through the reference potential connection portion are same.

2. The composite filter device according to claim 1, wherein
the substantially annular portion of the reference potential wiring line includes an opposing portion that faces the reference potential connection portion across the gap, that extends with the second end portion as a starting point, and that is connected to the reference potential; and
the longitudinally coupled resonator acoustic wave filter includes a plurality of IDT electrodes, and among the plurality of IDT electrodes, a number of IDT electrodes of the longitudinally coupled resonator acoustic wave filter connected to the reference potential connection portion is larger than a number of IDT electrodes of the longitudinally coupled resonator acoustic wave filter connected to the opposing portion.

3. The composite filter device according to claim 1, wherein the longitudinally coupled resonator acoustic wave filter of the first filter and the resonator of the second filter are both provided on the piezoelectric substrate.

4. The composite filter device according to claim 1, further comprising:
a mounting substrate that is a multilayer substrate including a plurality of layers; wherein
the inductor of the second filter is provided over the plurality of layers of the mounting substrate.

5. The composite filter device according to claim 1, wherein the second filter is a band elimination filter.

6. The composite filter device according to claim 5, wherein a pass band of the first filter and an attenuation band of the second filter have a same frequency range.

7. The composite filter device according to claim 1, wherein the second filter is a band pass filter.

8. The composite filter device according to claim 1, further comprising a common connection terminal connected to the first filter and the second filter.

9. The composite filter device according to claim 8, wherein the common connection terminal is an antenna terminal connected to an antenna.

10. The composite filter device according to claim 1, wherein the first filter is a reception filter.

11. The composite filter device according to claim 1, wherein composite filter device is an extractor.

12. The composite filter device according to claim 1, wherein the longitudinally coupled resonator acoustic wave filter has a configuration of one stage of 5 IDTs.

13. The composite filter device according to claim 1, wherein the first filter and the second filter are configured by one acoustic wave element chip.

14. The composite filter device according to claim 4, wherein the first filter and the second filter are configured by one acoustic wave element chip flip-chip mounted on the mounting substrate.

15. The composite filter device according to claim 4, wherein each of the layers of the mounting substrate includes wiring electrodes.

16. The composite filter device according to claim 15, wherein the mounting substrate includes through-electrodes to connect the wiring electrodes in the layers of the mounting substrate.

17. The composite filter device according to claim 2, wherein each of the plurality of IDT electrodes includes a pair of reflectors.

18. The composite filter device according to claim 2, wherein a number of the plurality of IDT electrodes is three, five, seven or nine.

19. The composite filter device according to claim 1, wherein the composite filter device is a duplexer.

20. The composite filter device according to claim 1, wherein the composite filter device is a multiplexer including three or more filters including at least one band pass filter.
